(19) United States
(12) Patent Application Publication
(10) Pub. No.: US 2009/0133906 A1
(43) Pub. Date: May 28, 2009

(54) FLEXIBLE PRINTED CIRCUIT BOARD AND MANUFACTURING METHOD THEREOF

(76) Inventor: Jae Myung BAEK, Suwon-si (KR)

Correspondence Address: CHA & REITER, LLC, 210 ROUTE 4 EAST STE 103, PARAMUS, NJ, 07652, US

(21) Appl. No.: 12/273,634

(22) Filed: Nov. 19, 2008

(30) Foreign Application Priority Data
Nov. 27, 2007 (KR) 2007-0121191

(51) Int. Cl. H05K 1/02; H05K 3/36

(52) U.S. Cl. 174/254; 29/830

(57) ABSTRACT

A flexible printed circuit board (FPCB) and FPCB manufacturing method that improves a signal transfer characteristic at a high speed. The FPCB includes an insulating layer having a signal pattern that transfers signals, a cover layer formed on the signal pattern, and a shielding layer formed at a position opposite to the signal pattern. The shielding layer faces at least one of the insulating layer and the cover layer across anspace formed there between.

### CLAIM OF PRIORITY

This application claims priority to an application entitled “FLEXIBLE PRINTED CIRCUIT BOARD AND MANUFACTURING METHOD THEREOF,” filed in the Korean Intellectual Property Office on Nov. 27, 2007 and assigned Serial No. 2007-0121191, the contents of which are incorporated herein by reference in its entirety.

### BACKGROUND OF THE INVENTION

1. Field of the Invention

The present invention relates to flexible printed circuit boards (FPCBs) and manufacturing methods thereof. More particularly, the present invention relates to a flexible printed circuit board (FPCB) having a shielding layer that can block electromagnetic interference (EMI) or electrostatic discharge (ESD).

2. Description of the Related Art

Flexible printed circuit boards (FPCBs) have been used for portable terminals, such as folder type portable terminals, slide type portable terminal, etc., which are configured to include two bodies, for example, a main body and an auxiliary body. That is, FPCBs have been in use for transmitting data between the main body and the auxiliary body of the portable terminal.

FPCBs are manufactured to certain standards that ensure the reliability of portable terminals because they are subject to being bent and undergoing stress when the main body and the auxiliary body are relatively rotated.

In particular, a slide type portable terminal is required to maintain the reliability of the FPCB during operations because the FPCB undergoes a small bend radius during the process of the sliding operation. Therefore, the flexible portion of the FPCB is configured to have a thin layer structure so that it can be flexibly bent during the process of a sliding operation.

FIG. 1 is a cross-sectional view illustrating a conventional flexible printed circuit board (FPCB) 1 having a single layer. This single layer FPCB 1 includes a base layer and a cover layer. The base layer includes an insulating layer 2 and a signal layer 3 having a data line. The cover layer includes an adhesive layer 4 and a cover insulating layer 5. The single layer FPCB 1 forms a connector (not shown) at both ends to be connected to an external printed circuit board (not shown), i.e., a printed circuit board (not shown) of a main body or a printed circuit board (PCB, not shown) of an auxiliary body. The FPCB 1 forms a fixing portion 6, relatively thick and hard, at both ends thereof, where the fixing portion 6 includes a conductive layer 6a and a plating layer 6b that are bonded to both ends. The conductive layer 6a may be formed as a metal film, such as a copper film. Electrical connection between the conductive layer 6a and the signal layer 3 is achieved through a via-hole 7. The plating layer 6b is formed through a plating process. During the formation of the plating layer 6b, the inner wall of the via-hole 7 is also filled with a metal.

In recent years, as the number of multimedia functions has increased in portable terminals, the amount of transmission data has increased rapidly and the data transmission rate has become much faster. To this end, the data is transmitted using a plurality of data lines. The data lines, however, must be shielded to block EMI emissions. The data lines are also required to resolve interference caused by external signals, such as a transmission signal of a portable terminal, or ESD generations.

In order to resolve problems caused by EMI emissions or ESD generations, flexible printed circuit boards (FPCBs) having a shielding layer have been developed as illustrated in FIG. 2.

Referring now to FIG. 2, an FPCB 10 includes shielding layers 15 and 22 for shielding EMI emissions, etc. that are bonded on the upper surface of a cover insulating layer 14 and on the lower surface of an insulating layer 11, correspondingly and respectively. The FPCB 10 having shielding layers also includes the insulating layer 11, a signal layer 12, an adhesive layer 13, and the cover insulating layer 14, which are stacked, in order, the same as the single layer FPCB 1 of FIG. 1. It also includes conductive layers 18 and 20 each of which is patterned with externally connected electrodes 18a and 20a and ground electrodes 18b and 20b, electrically connected to an external PCB (not shown). The conductive layers 18 and 20 form coated layers 19 and 21 thereon, correspondingly and respectively. The shielding layers 15 and 22 are comprised of conductive adhesive layers 15a and 22a and dielectric films 15b and 22b formed on the conductive adhesive layers 15a and 22a, correspondingly and respectively. The conductive adhesive layer 15a serves to shield EMI emissions. The FPCB 10 has shielding layers that include adhesive layer 16, and a via hole 17, both of which having structures that are the same as the FPCB 1 of FIG. 1.

As described above, the conventional FPCB shown in FIG. 2 has shielding layers that can substantially resolve underlying problems with EMI emissions and ESD generations. However, the conventional FPCP such as shown in FIG. 2 still suffers from the degradation of signal transmission characteristics when signal transmission is performed at a high speed.

More particularly, the shielding layers 15 and 22 shown in FIG. 2 are bonded to the cover insulating layer 14 and the insulating layer 11, and thus the data lines of the signal layer 12 are formed very close to the conductive adhesive layer 15a of the shielding layer 15. As a result, the capacitance increases between the conductive adhesive layer 15a of the shielding layer 15 and the data lines of the signal layer 12, and, accordingly, the impedance showing a characteristic of a data line as a transmission path decreases, thereby causing an impedance mismatch. The closer the distance between the data lines and the conductive adhesive layer 15, the greater is the conductive loss of the transmission path, and the greater is the dielectric loss generated by the dielectric characteristics of the insulating layer 11, the adhesive layer 13 and the cover insulating layer 14.

### SUMMARY OF THE INVENTION

The present invention provides a flexible printed circuit board (FPCB) that can block EMI emission and ESD without a decrease in the durability and reliability of the FPCB, and provide a superior signal transmission characteristic at a high speed. The present invention also includes a method of manufacturing the FPC.

In accordance with an exemplary embodiment of the present invention, the present invention provides a flexible printed circuit board (FPCB) including: an insulating layer; a signal layer formed on the insulating layer and comprises a circuit pattern; a cover layer formed on the signal layer and the insulating layer; and at least one shielding layer facing at least one of the insulating layer and the cover layer, across a space formed therebetween. Preferably, at least one shielding layer is formed on another insulating layer, which in turn is bonded to an adhesive layer formed at both ends of at least one of the insulating layer and the cover layer.

Preferably, the FPCB also includes: fixing portions, each of which is placed at both ends thereof and form an electrical interface that is connected to an external printed circuit board (PCB); and a flexible portion that is formed between the fixing portions and flexibly bent when the external PCBs are moved, in which the flexible portion forms the space therein. Preferably, the space is filled with air.

In accordance with another exemplary embodiment of the present invention, a method for manufacturing a flexible printed circuit board (FPCB) includes: preparing a first single layer FPCB, which forms an insulating layer, a signal layer and a cover layer, and at least one second single layer FPCB which forms an insulating layer and a signal layer; forming an adhesive layer on the surface of any of the insulating layer and cover layer of the first single layer FPCB, at both ends of the first single layer FPCB; bonding at least one second single layer FPCB to the adhesive layer and forming at least one space between the first single layer FPCB and at least one second single layer FPCB; removing the signal layer of at least one second single layer FPCB except for both ends of the signal layer and exposing a part of the insulating layer of at least one second single layer FPCB; and forming a shielding layer, which comprises a conductive layer, in the exposed part of the insulating layer and a part of both ends of the signal layer of at least one second single layer FPCB.

### BRIEF DESCRIPTION OF THE DRAWINGS

The features and advantages of the present invention will become more apparent from the following detailed description in conjunction with the accompanying drawings, in which:

FIG. 1 is a cross-sectional view illustrating a conventional flexible printed circuit board (FPCB);

FIG. 2 is a cross-sectional view illustrating a conventional FPCB having a shielding layer;

FIG. 3A and FIG. 3B are cross-sectional views illustrating an FPCB according to a first exemplary embodiment of the present invention;

FIG. 4A and FIG. 4B are eye diagrams according to a conventional FPCB and an FPCB according to an exemplary embodiment of the present invention, respectively;

FIG. 5 is a cross-sectional view illustrating an FPCB according to a second exemplary embodiment of the present invention;

FIG. 6 is a cross-sectional view illustrating an FPCB according to a third exemplary embodiment of the present invention;

FIG. 7A to FIG. 7D are cross-sectional views that describe an FPCB manufacturing method according to a first exemplary embodiment of the present invention; and

FIG. 8A to FIG. 8C are cross-sectional views that describe an FPCB manufacturing method according to a second exemplary embodiment of the present invention.

### DETAILED DESCRIPTION

Hereinafter, exemplary embodiments of the present invention are described in detail with reference to the accompanying drawings. The same reference numbers are used throughout the drawings to refer to the same or similar parts. Detailed descriptions of well-known functions and structures incorporated herein may be omitted to avoid obscuring appreciation of the subject matter of the present invention by a person of ordinary skill in the art.

### Exemplary Embodiment 1 of FPCB

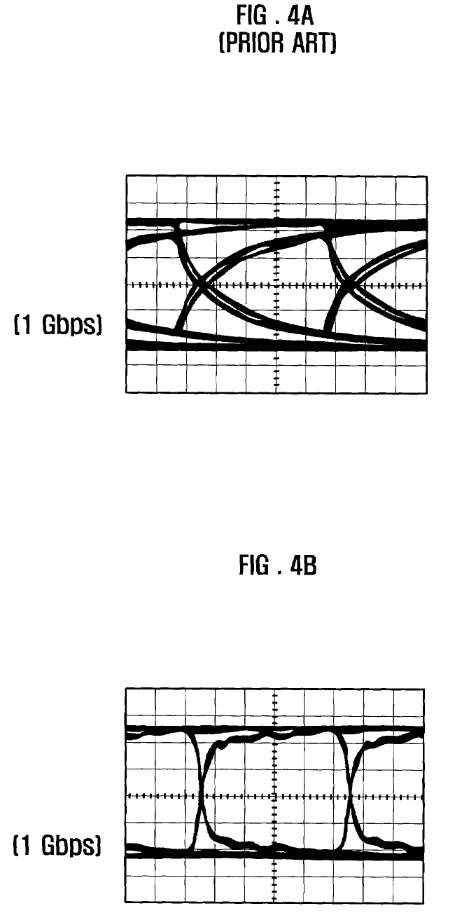

FIG. 3A and FIG. 3B are cross-sectional views illustrating an FPCB 100 according to a first exemplary embodiment of the present invention.

As shown in FIG. 3A, the FPCB 100 comprises a single layer FPCB 110 as a basic structure, which includes a base insulating layer 111, a signal layer 112, an adhesive layer 114 and a cover insulating layer 115 that are stacked in order. The insulating layer 111 and the signal layer 112 comprise a base layer 113. The adhesive layer 114 and the cover insulating layer 115 comprise a cover layer 116. Another adhesive layer (not shown) may be further formed between the base insulating layer 111 and the signal layer 112. The base insulating layer 111 or the cover insulating layer 115 can be made, or example, of polyimide. The signal layer 112 can be made of, for example, metals such as copper, and patterned with a certain type of pattern for data lines.

Still referring to FIG. 3A, a first adhesive layer 141 (the attached MPEP sample with the drawings shows a recommended cross-section for adhesive) is formed at both ends of the upper surface of the cover insulating layer 115. A second adhesive layer 142 is formed on the lower surface of the base insulating layer 111, at both ends of the insulating layer 111. A first insulating layer 121 is bonded to both ends of the cover insulating layer 115 by the first adhesive layer 141. A second insulating layer 131 is bonded to both the ends of the lower surface of the insulating layer 111 by the second adhesive layer 142. The first and second insulating layers 121 and 131 can be made of the same polyimide as the base insulating layer 111. As will be described in the manufacturing method, the first and second insulating layers 121 and 131 each are configured to include a single layer FPCB as a base layer, similar to the base insulating layer 111 including a single layer FPCB 110, illustrated in FIG. 3A.

The first insulating layer 121 is formed to be spaced apart from the cover insulating layer 115 by the first adhesive layer 141, forming a first space 151 therebetween, so that the first insulating layer 121 faces the upper surface of the cover insulating layer 115 across the first space 115. That is, the first space 151 is defined by the first adhesive layer 141, the first insulating layer 121, and the cover insulating layer 115. The first adhesive layer 141 is approximately 25˜35 μm thick. Similarly, the second insulating layer 131 is formed to be spaced apart from the base insulating layer 111 by the second adhesive layer 142, forming a second space 152 therebetween, so that the second insulating layer 131 faces the lower surface of the base insulating layer 111 across the second space 152. That is, the second space 152 is defined by the second adhesive layer 142, the second insulating layer 131 and the base insulating layer 111. The second adhesive layer 142 may have the same thickness as the first adhesive layer 141 or a different thickness. In general, the first and second spaces 151 and 152 are filled with air.

The first insulating layer 121 and the cover insulating layer 115 are spaced apart from each other by the first space 151. Similarly, the second insulating layer 131 and the base insulating layer 111 are spaced apart from each other by the second space 152. Each space formed by the first and second spaces 151 and 152 is identical to the thickness of the first and second adhesive layer 141 and 142 when the FPCB 100 is not bent, but differs from the thickness of the first and second adhesive layer 141 and 142 when the FPCB 100 is bent. If the first and second adhesive layers 141 and 142 each are 25 μm thick, each spacing of the first and second spaces 151 and 152 is varied in a range of 10˜100 μm according to the bend of the FPCB 100.

The first shielding layer 160 is formed on a surface of the first insulating layer 121, which is an opposite surface of the first insulating layer 121 to which the first adhesive layer 141 is bonded, where the opposite surface faces the cover insulating layer 115. The first shielding layer 160 includes a conductive adhesive layer 161 and a dielectric film 162 formed thereon. The conductive adhesive layer 161 bonds the first shielding layer 160 to the first insulating layer 121 and blocks one or both of EMI emissions or ESD. The second shielding layer 170 is formed on a surface of the second insulating layer 131, which is an opposite surface of the second insulating layer 131 to which the second adhesive layer 142 is bonded, where the opposite surface faces the base insulating layer 111. Similar to the first shielding layer 160, the second shielding layer includes a conductive adhesive layer 171 and a dielectric film 172 formed thereon. The conductive adhesive layer 171 has the same function as the conductive adhesive layer 161 of the first shielding layer 160.

Still referring to FIG. 3A, the first and second shielding layers 160 and 170 may directly form a conductive layer on the first and second insulating layers 121 and 131, respectively, and a protective dielectric layer thereon. The conductive layer for blocking EMI emissions, etc. may be formed of metals, for example, such as silver, etc., that are processed by evaporation or sputtering, etc. Also, the conductive layer may be formed of a metal paste that is directly coated on one or more of the first and second insulating layers 121 and 131.

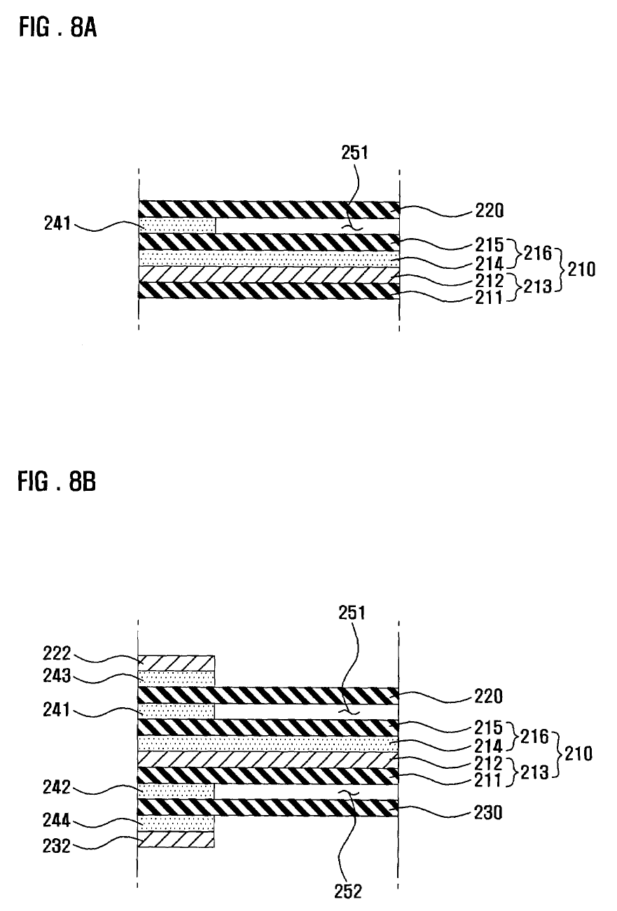

The first and second insulating layers 121 and 131 form conductive layers 122 and 132 on the surfaces, on which the shielding layers 160 and 170 are formed, at both ends thereof, respectively. For example, the first insulating layer 121 forms the first conductive layer 122 at both ends thereof and the second insulating layer 131 forms the second conductive layers 132 at both ends thereof. The first and second conductive layers 122 and 132 are each patterned with externally connected electrodes 122a and 132a, which are connected to an external PCB, and ground electrodes 122b and 132b that are connected to the ground level. The first and second conductive layers 122 and 132 have conductive layers 124 and 134 formed thereon, respectively. The first and second conductive layers 122 and 32 are the remaining portions that are formed as the signal layers 122 and 132 of the base layers 123 and 133 of the second and third single layer FPCBs 120 and 130 are partially removed, respectively, as shown in FIGS. 7C and 7D.

The conductive adhesive layers 161 and 171 of the first and second shielding layers 160 and 170 are each electrically connected to the ground electrodes 122b and 132b of the first and second conductive layers. As shown in FIG. 3A, the FPCB 100 is implemented such that the conductive adhesive layers 161 and 171 are each formed to cover the ground electrodes 122b and 132b of the first and second conductive layers. However, it should be understood that the present invention is not limited to include this structure. The first and second conductive layers 122 and 132 are each electrically connected to the signal layer 112 through the first and second via-holes 181 and 182.

The first and second conductive layers 122 and 132 and the first and second adhesive layers 141 and 142 may be aligned such that at least one end of each of them is aligned along the same straight line in the vertical direction. As shown in FIG. 3A, the FPCB is implemented such that one end of them is aligned along the same straight line in the vertical direction. However, it should be understood that the present invention is not limited to this structure.

The FPCB 100 comprises a flexible portion and a fixing portion. The flexible portion is flexibly bent when the main body of the portable terminal is moved relative to the auxiliary body. The fixing portion serves as an interface that electrically connects the main body and the auxiliary body of the portable terminal. The FPCB 100, according to an exemplary embodiment of the present invention, forms the spaces 151 and 152 in the flexible portion, so that the stress, generated when the main body and auxiliary body of the portable terminal are bent relative to each other, is properly dispersed to the spaces 151 and 152.

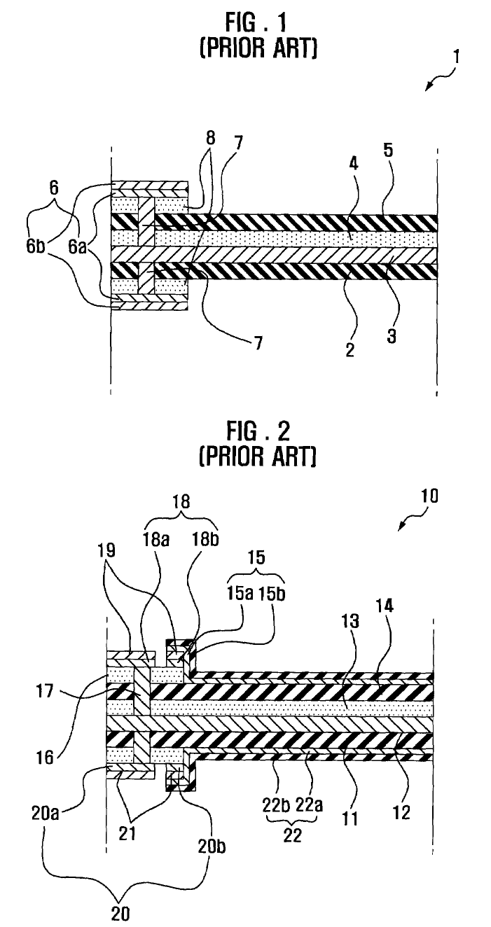

Therefore, although the FPCB 100 according to the present invention includes the shielding layers 160 and 170, it has a folding resistance and a flex resistance that are equal to or greater than those of the conventional single layer FPCB 1 of FIG. 1. As shown in the markings in the lower portion of FIG. 3A, the flexible portion and the fixing portion are divided by the vertical straight line formed by one-side ends of the first and second conductive layers 122 and 132 and the first and second adhesive layers 141 and 142.

FIG. 3B provides a cross-sectional view illustrating the FPCB 100 of FIG. 3A, taken along line I-I. As shown in FIG. 3B, the data line of the signal layer 112 serves as a waveguide that transfers two differential signals that have equal amplitude but opposite phase. In recent years, as portable terminals have begun including multi-media functions, the amount of data transmitted through an FPCB has rapidly increased. Accordingly, there is a need to reduce the number of data lines through serialization of the data line and instead increase the transmission speed of the data line.

As shown in FIG. 3B, when the data line is realized as a waveguide that transfers differential signals, the FPCB can achieve a high data transmission speed.

As shown in FIG. 3A and FIG. 3B, the FPCB 100 can be configured such that the shielding layers 160 and 170, connected electrically to the ground electrodes 122b and 132b, are placed between the spaces 151 and 152, facing the data line of the signal line 112. Therefore, the FPCB 100 is able to prevent impedance matching due to the decrease of the characteristic impedance of a transmission line and reduce the conductive loss and dielectric loss. The data line of the FPCB 100 serves as a transmission line that transmits data at a high speed, where such a transmission line has a property that the larger the capacitance the smaller the characteristic impedance thereof. In general, the transmission line for a differential signal has a characteristic impedance of 100Ω.

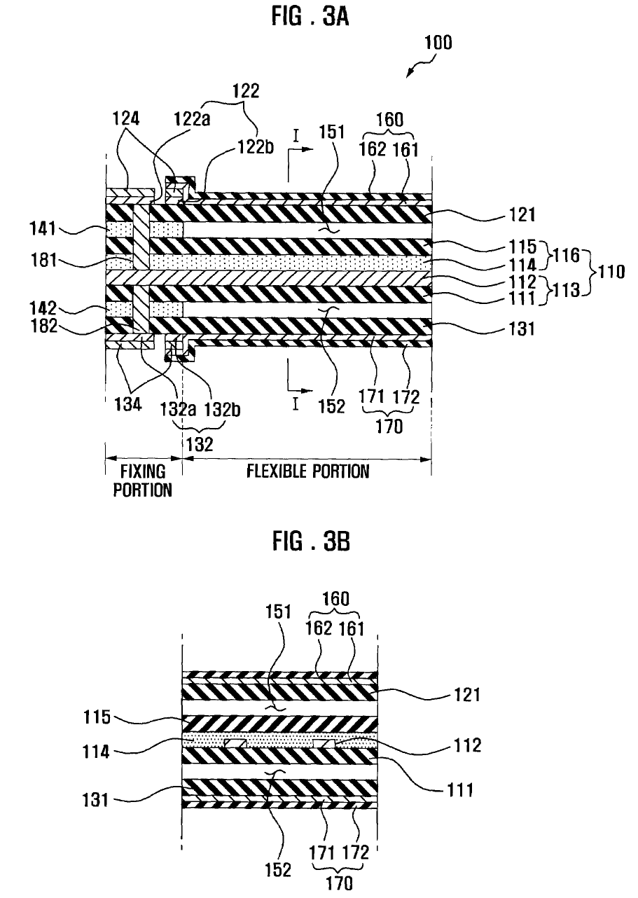

The conventional FPCB 10 shown in FIG. 2 is configured such that the shielding layers 15 and 22 are directly bonded to the cover insulating layer 14 and the insulating layer 11. Therefore, the conventional FPCB of FIG. 2 has a relatively large capacitance between the shielding layers 15 and 22 and the signal layer, and thus the characteristic impedance of the entire transmission lines is decreased to approximately 40Ω.

On the contrary, as shown in FIG. 3A and FIG. 3B, the FPCB 100 according to a first exemplary embodiment of the present invention is configured such that the respective shielding layers 160 and 170 are spaced apart from the signal layer 112 at a certain spacing formed by the respective spaces 151 and 152. Therefore, the FPCB 100 has a relatively small capacitance, and thus the characteristic impedance is also relatively small. The spacing formed by each of the spaces 151 and 152 is varied in a range of 10˜100 μm, the characteristic impedance maintains more than 90Ω.

The conductive loss is affected by resistance of the metal forming the data line, and/or by the structure of the transmission line. In particular, the closer the distance between the shielding layers, connected electrically to the ground, and the signal layer, the larger is the conductive loss. Therefore, the FPCB 100 according to a first exemplary embodiment of the present invention has a relatively small amount of conductive loss, compared to the conventional FPCB 10 of FIG. 2.

The dielectric loss is varied according to the dielectric constant of materials inserted into between the shielding layers and the signal layer. The FPCB 100 of the present invention fills the spaces 151 and 152 that undergoes no dielectric loss with air, and thus reduces the dielectric loss by the materials inserted into between the shielding layers 160 and 170 and the signal layer 112 while electromagnetic waves generated between the signal layer 112 and the shielding layers 160 and 170 are propagating along the FPCB 100.

As described above, the FPCB 100 does not reduce the characteristic impedance, thereby preventing the impedance mismatching previously known heretofore in conventional devices. The FPCB 100 can decrease both the conductive loss and the dielectric loss, thereby providing a superior high speed signal transmission characteristic.

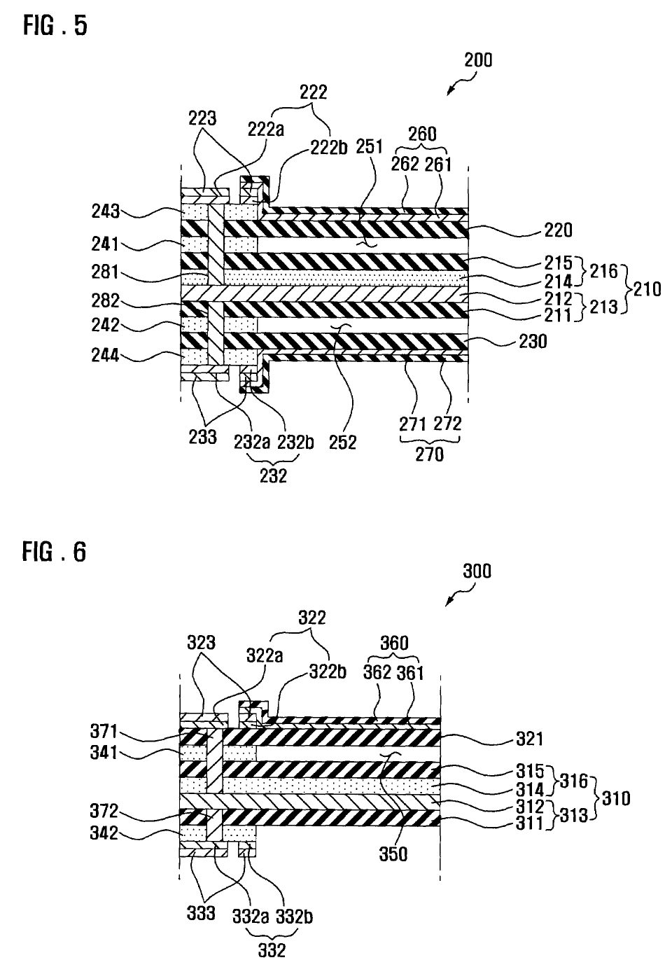

FIG. 4A and FIG. 4B are eye diagrams according to a conventional FPCB 10 and an FPCB 100 according to an exemplary embodiment of the present invention, respectively.

In a digital data transmission system, the eye diagram is used to measure empirically the un-stability of transmission channel and shows eye patterns by overlaying multiple bits of signals through an oscilloscope. When the eye diagram becomes much wider, the transmission of the signals is better. On the contrary, when the eye diagram becomes narrower, the transmission of the signals is prone to failure. The larger the transmission line loss the flatter the signal shape of the eye pattern.

FIG. 4A is an eye diagram when a signal of 1 Gbps is input to the conventional FPCB 10, where the eye shape is narrow and the shape of signal becomes substantially flatter. On the contrary, the eye diagram of FIG. 4B is completely opened and the shape of signal is not laid. As such, the FPCB 100 of the present invention shows a remarkable signal transmission characteristic when transmitting signals at a high speed of 1 Gbps, compared to the conventional FPCB 10.

### Exemplary Embodiment 2 of FPCB

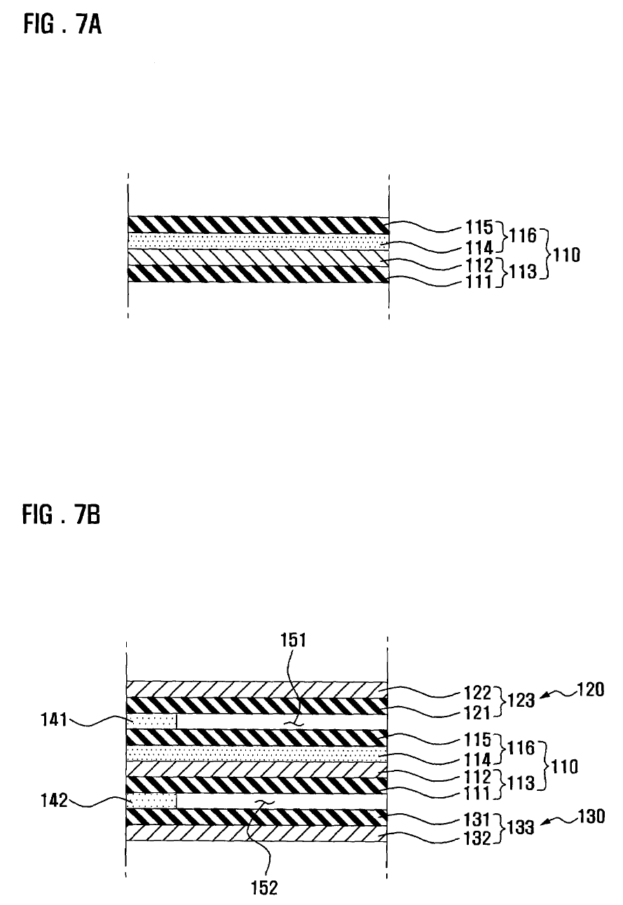

FIG. 5 is a cross-sectional view illustrating an FPCB 200 according to a second exemplary embodiment of the present invention.

Similar to the FPCB 100 of FIG. 3A, the FPCB 200 in FIG. 5, according to a second exemplary embodiment of the present invention, has a single layer FPCB 210 as a basic structure. The stack layer structure of the single layer FPCB 210 comprises a base layer 213 and a cover layer 216 stacked on the base layer 213. The base layer 213 includes an insulating layer 211 and a signal layer 212 formed thereon. The cover layer 216 includes an adhesive layer 214 and a cover insulating layer 215. A first insulating layer 220 is bonded to the cover insulating layer 215 by a first adhesive layer 241, forming a first space 251 therebetween. Similarly, a second insulating layer 230 is bonded to the insulating layer 211 by a second adhesive layer 242, forming a second space 252 therebetween.

Unlike the first exemplary embodiment of the present invention, the FPCB 200 according to a second exemplary embodiment is configured such that the first and second insulating layers 220 and 230 are not insulating layers forming a base layer of a single layer FPCB, but rather comprise a single layer formed by an insulating material. In the first exemplary embodiment, the first and second insulating layers 121 and 131 are each an insulating layer that remains when the signal layers 122 and 132 of the single layer FPCB 120 and 130 as the base layers 123 and 133 are each removed. On the contrary, in the second exemplary embodiment, the first and second insulating layers 220 and 230 are formed from the base layer of the single layer FPCB but a single layer formed by an insulating material. Therefore, the material of the first and second insulating layers 220 and 230 may be different from that of the insulating layer 211.

Still referring to FIG. 5, a third adhesive layer 243 is formed at both ends of the upper surface of the first insulating layer 220. A first conductive layer 222 is bonded to both ends of the first insulating layer 220 by the third adhesive layer 243. Similarly, a fourth adhesive layer 244 is formed at both ends of the lower surface of the second insulating layer 230. A second conductive layer 232 is bonded to both ends of the second insulating layer 230 by the fourth adhesive layer 244. Unlike the first exemplary embodiment, the first and second conductive layers 222 and 232 of the second exemplary embodiment are not a portion that remains when a part of the signal layer forming the base layer of the single layer FPCB is removed but instead they are individually bonded thereto by the third and fourth adhesive layers 243 and 244. The first and second conductive layers 222 and 232 of the second exemplary embodiment are implemented by a metal film, such as a copper film. Similar to the first exemplary embodiment, the first and second conductive layers of the second exemplary embodiment are patterned with externally connected electrodes 222a and 232a and ground electrodes 222b and 232b, respectively. These electrodes form plating layers 223 and 232 thereon, respectively. The first conductive layer 222 is connected electrically to the signal layer 212 through a first via-hole 281. The second conductive layer 232 is also connected electrically to the signal layer 212 through a second via-hole 282.

Shielding layers 260 and 270 of the second exemplary embodiment are the same as the shielding layers 160 and 170 of the first exemplary embodiment. That is, the first insulating layer 220 forms the first shielding layer 260 on the upper surface thereof, where the first shielding layer 260 comprises a conductive adhesive layer 261 and a dielectric film 262. Similarly, the second insulating layer 230 forms the second shielding layer 270 on the lower surface thereof, where the second shielding layer 270 comprises a conductive adhesive layer 271 and a dielectric film 272. Similar to the first exemplary embodiment, the respective first and second shielding layers 260 and 270 are formed to face the signal layer 212 across the first and second spaces 251 and 252. The conductive adhesive layers 261 and 271 of the first and second shielding layers 260 and 270 are each electrically connected to the ground electrodes 222b and 232b of the first and second conductive layers. Similar to the first exemplary embodiment, the first and second shielding layers 260 and 270 does not need to be formed in such a way that their both ends completely cover the ground electrodes 222b and 232b of the first and second conductive layers but instead they may be connected only electrically to the ground electrodes 222b and 232b.

### Exemplary Embodiment 3 of FPCB

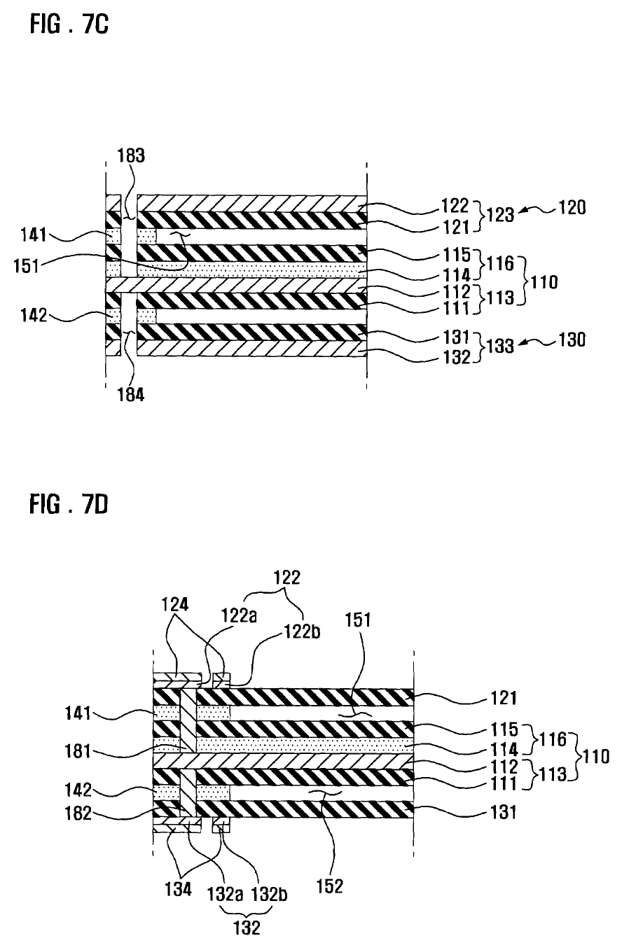

FIG. 6 is a cross-sectional view illustrating an FPCB 300 according to a third exemplary embodiment of the present invention. The FPCB 300 according to the third exemplary embodiment is different from the first and second embodiments in that a shielding layer 360 is formed on only any one of the surfaces of the single layer FPCB 310 as a basic structure.

As shown in FIG. 6, the FPCB 300 according to a third exemplary embodiment of the present invention is the same as the first and second exemplary embodiments in that it has a single layer FPCB 310 as a basic structure. The single layer FPCB 310 comprises a cover insulating layer 315. A first adhesive layer 341 is formed at both ends of the upper surface of the cover insulating layer 315. A shielding insulating layer 321 is bonded to both ends of the cover insulating layer 315 by the first adhesive layer 341. A shielding layer 360 is bonded to a surface of the shielding insulating layer 321 which is opposite to the other surface that faces the cover insulating layer 315. Although the shielding insulating layer 321 is formed to face the cover insulating layer 315 as shown in FIG. 6, it should be understood that the present invention is not limited by the structure. For example, the exemplary embodiment may be modified such that a shielding insulating layer is formed to face an insulating layer 311. That is, the third exemplary embodiment can be implemented such that the shielding insulating layer 321 is formed to face the cover insulating layer 315 or the insulating layer 311 of the single layer FPCB 310.

A space 350 is formed between the cover insulating layer 315 and the shielding insulating layer 321 and filled with air. Similar to the first adhesive layer 141 of the first exemplary embodiment, the first adhesive layer 341 of the third exemplary embodiment is about 25˜35 μm thick.

Still referring to FIG. 6, the shielding insulating layer 321 forms a first conductive layer 322 on its upper surface at its both ends and the shielding layer 360 on its surface on which the first conductive layer 322 is not formed. The first conductive layer 322 is patterned with an externally connected electrode 322a and a ground electrode 322b. The externally connected electrode 322a and a ground electrode 322b form a plating layer 323 thereon. Similar to the first and second exemplary embodiments, the shielding layer 360 comprises a conductive adhesive layer 361 and a dielectric film 362. The conductive adhesive layer 361 is connected electrically to the ground electrode 322b. Similar to the first and second conductive layers 122 and 132 of the first exemplary embodiment, the first conductive layer 322 is formed by a portion that remains when a portion of the signal layer is removed from the base layer of the single layer FPCB. Although the shielding insulating layer 321 of FIG. 6 is formed as a portion of signal layer is removed from the base layer of the single layer FPCB, it should be understood that the present invention is not limited by this exemplary embodiment. For example, similar to the FPCB 200 of the second exemplary embodiment, the shielding insulating layer 321 may be implemented by a single insulating layer formed by a dielectric material. In that case, the shielding insulating layer further forms an adhesive layer and then a metal film is bonded to the adhesive layer.

The insulating layer 311 forms a second adhesive layer 342 thereon, so that the second adhesive layer 342 bonds the second conductive layer 332 to the insulating layer 311. The second conductive layer 322 includes an externally connected electrode 332a and a ground electrode 322b. The externally connected electrode 332a and the ground electrode 322b form a plating layer 333 thereon. Unlike the first conductive layer 322, the second conductive layer 332 is not formed from a signal layer of the single layer FPCB but rather by a metal film, for example, such as a copper film, as the first and second conductive layers 222 and 232 of the second exemplary embodiment. The first and second conductive layers 322 and 332 are connected electrically to the signal layer 312 by the first and second via-holes 371 and 372.

In the third exemplary embodiment, the FPCB 300 comprises one shielding layer 360 on the cover insulating layer 315 or the insulating layer 311. It is preferable that the shielding layer 360 is formed to be placed close to an antenna through which RF signals of the portable terminal are transmitted. Because the transmitted RF signals of the portable terminal may be prone to interfere with the signals that are transferred through the FPCB at a high speed or the signals that are transferred through the FPCB at a high speed may be prone to interfere with the received RF signals of the portable terminal. It is preferable that the shielding layer is placed at both the cover insulating layer 315 and the insulating layer 311 to effectively block EMI emissions. However, it is possible to form a shielding layer on either side of the FPCB that requires shielding, considering the manufacturing complexity and costs. From this point of view, the third embodiment is also preferred embodiment of the present invention.

### Exemplary Embodiment 1 of FPCB Manufacturing Method

FIG. 7A to FIG. 7D are cross-sectional views that describe an FPCB manufacturing method according to a first exemplary embodiment of the present invention.

First, as shown in FIG. 7A and FIG. 7B, a first single layer FPCB 110 is prepared that is configured to include a base layer 113 and a cover layer 116 stacked on the base layer 113, where the base layer 113 comprises a base insulating layer 111 and a signal layer 112 formed thereon, and the cover layer 116 comprises an adhesive layer 114 and a cover insulating layer 115 formed thereon. A first adhesive layer 141 is bonded on the upper surface of the cover insulating layer 115 at both ends of the first single layer FPCB 110. A second single layer FPCB 120 is bonded on the first adhesive layer 141. Unlike the first single layer FPCB 110, the second single layer FPCB 120 has a base layer 123 that comprises an insulating layer 121 and a signal layer 122 formed thereon, without forming a cover layer. When the second single layer FPCB 120 is bonded onto the first single layer FPCB 110 by the first adhesive layer 141, a first space 151 is also formed between the cover insulating layer 115 of the first single layer FPCB 110 and the insulating layer 121 of the second single layer FPCB 120.

On the other hand, a second adhesive layer 142 is formed on the lower surface of the base insulating layer 111 at both ends of the first single layer FPCB 110 and then a third single layer FPCB 130 is bonded on the second adhesive layer 142. The third single layer FPCB 130 has the same stack structure as the second single layer FPCB 120. A second space 152 is formed between the base insulating layer 111 of the first single layer FPCB 110 and the insulating layer 131 of the third single layer FPCB 130.

After that, as shown in FIG. 7C, a first through-hole 183 is formed extending from the surface of the signal layer 122 of the second single layer FPCB 120 through the signal layer 112 of the first single layer FPCB 110. Similarly, a second through-hole 184 is formed extending from the surface of the signal layer 132 of the third single layer FPCB 130 through the signal layer 112 of the first single layer FPCB 110. The first and second through-holes 183 and 184 may be each individually formed or may be formed as a single through-hole that extends through from the surface of the signal layer 122 of the first single layer FPCB 120 to the surface of the signal layer 132 of the third single layer FPCB 130.

Next, as shown in FIG. 7D, the signal layers 122 and 132 of the second and third single layer FPCB 120 and 130 undergo a plating process and form plating layers 124 and 134 thereon, respectively. While the plating layers 124 and 134 are forming, the first and second through-holes 183 and 184 are filled with metals, so that first and second via-holes 181 and 182 are formed.

Next, both ends of the signal layers 122 and 132, on which the plating layers 124 and 134 are formed, are patterned with externally connected electrodes 122a and 132a and ground electrodes 122b and 132b, respectively. The remaining portions except for both the ends of the signal layers 122 and 132, which correspond to a flexible portion, are removed, so that the insulating layers 121 and 131 can be exposed. Afterwards, the first and second shielding layers 160 and 170 are each formed on the exposed insulating layers 121 and 131 of the second and third single layer FPCBs 120 and 131.

### Exemplary Embodiment 2 of FPCB Manufacturing Method

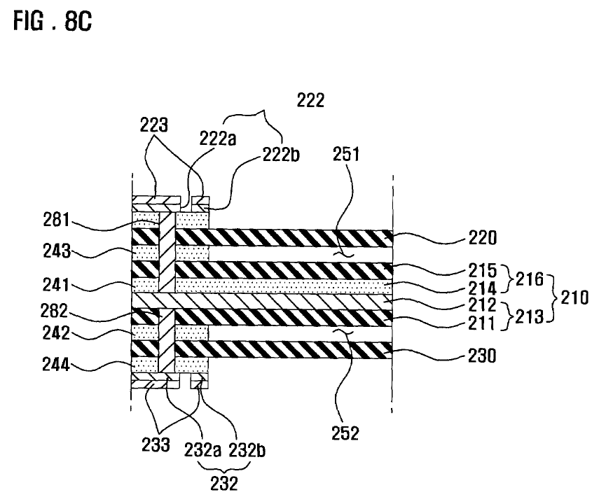

FIG. 8A to FIG. 8C are cross-sectional views that describe an FPCB manufacturing method according to a second exemplary embodiment of the present invention.

First, as shown in FIG. 8A, a single layer FPCB 210 is prepared that is stacked in order with an insulating layer 211, a signal layer 212, an adhesive layer 214 and a cover insulating layer 215. A first adhesive layer 241 is bonded on the upper surface of the cover insulating layer 215 at both ends of the single layer FPCB 210. After that, a first insulating layer 220 made of a dielectric material is bonded to the first adhesive layer 241, forming a first space 251 between the first insulating layer 220 and the cover insulating layer 215. Unlike the insulating layer 121 of the second single layer FPCB 120 that is formed by the method according to the first exemplary embodiment, the first insulating layer 220 comprises a single insulating layer preferably made of a dielectric material. Therefore, unlike the method of the first exemplary embodiment, the method according to the second embodiment does not require the removal of a portion corresponding to a flexible portion from a signal layer of the respective single layer FPCBs.

As shown in FIG. 8B, a third adhesive layer 243 is bonded on the upper surface of the first insulating layer 220 at both ends of the FPCB, which is opposite the surface on which the first adhesive layer 241 is bonded. After that, a first conductive layer 222, formed by a metal film, is bonded onto the third adhesive layer 243.

Similarly, a second adhesive layer 242 is bonded on the lower surface of the insulating layer 211 at both ends of the single layer FPCB 210. After that, a second insulating layer 230 made of a dielectric material is bonded to the second adhesive layer 242, forming a second space 252 between the second insulating layer 230 and the insulating layer 211. Next, a fourth adhesive layer 244 is bonded on the upper surface of the second insulating layer 230 at both ends of the FPCB, which are opposite the surface on which the second adhesive layer 242 is bonded. After that, a second conductive layer 232, formed by a metal film, is bonded onto the fourth adhesive layer 244.

After the first insulating layer 220 and the first conductive layer 222 are formed in order, the second insulating layer 230 and the second conductive layer 232 may be formed. In addition, after the first and second insulating layers 220 and 230 are formed, the first and second conductive layers 222 and 232 may be formed, respectively.

Next, as shown in FIG. 8C, a through-hole is formed extending from the surfaces of the first and second conductive layers 222 and 232 through the signal layer 212. After that, the first and second conductive layers 222 and 232 undergo a plating process and form plating layers 223 and 233 thereon. While the plating layers 223 and 233 are forming, the through-hole is filled with a metal, so that first and second via-holes 281 and 282 are formed. Next, the first and second conductive layers 222 and 232 forming the plating layers 223 and 233 are patterned with externally connected electrodes 222a and 232a and ground electrodes 222b and 232b, respectively. Afterwards, the first and second shielding layers 260 and 270 are formed on the first and second insulating layers 220 and 230 thereon.

As described above, since the space is filled with air and formed between the shielding layer and the signal pattern that is formed in the signal layer, the flexible printed circuit board (FPCB) according to the present invention can increase the distance therebetween. That is, since the shielding layer is spaced apart from the signal layer at a certain distance, the FPCB does not causes the impedance mismatching and the degradation of the high speed signal transmission characteristic, such as conductive loss increase, dielectric loss increase, etc., thereby blocking EMI and ESD. Furthermore, the FPCB can improve its durability and reliability.

In addition, the FPCB according to the present invention has superior durability and reliability, and a superior signal transmission characteristic at a high speed, so that it can block EMI emission and ESD phenomenon. The method according to the present invention provides a way to manufacture the novel construction of the FPC to have superior durability and reliability, and a superior signal transmission characteristic at a high speed.

Although exemplary embodiments of the present invention have been described in detail hereinabove, it should be understood that many variations and modifications of the basic inventive concept herein described, which may be apparent to those skilled in the art, will still fall within the spirit and scope of the exemplary embodiments of the present invention as defined in the appended claims. For example, although it is preferred that air fills the spaces, it is possible that another gas or possible a flexible material, such as a foam, etc., could be installed there between.

What is claimed is:

1. A flexible printed circuit board (FPCB) comprising:
a base insulating layer;
a signal layer formed on the base insulating layer and including a circuit pattern;
a cover layer formed on the signal layer and the base insulating layer; and
at least one shielding layer facing at least one of the base insulating layer and the cover layer, across a space formed therebetween.

2. The FPCB of claim 1, wherein the at least one shielding layer is formed on another insulating layer located above the base insulating layer and is bonded to an adhesive layer that is formed at both ends of at least one of the base insulating layer and the cover layer.

3. The FPCB of claim 2, wherein the FPCB comprises:
a plurality of fixing portions, each fixing portion of said plurality of fixing portions being arranged at both ends of the FPCB and forming an electrical interface that is connected to an external printed circuit board (PCB); and
a flexible portion formed between the fixing portions and flexibly bent when the external PCBs are moved, in which the flexible portion forms the space therein.

4. The FPCB of claim 1, wherein each of the at least one shielding layer comprises a shielding film, in which the shielding film comprises a conductive adhesive layer, and a dielectric film formed on the conductive adhesive layer.

5. The FPCB of claim 1, wherein each of the at least one shielding layer comprises:
a conductive layer; and
a protective dielectric layer formed on the conductive layer.

6. The FPCB of claim 4, wherein the at least one shielding layer comprises:
a first shielding layer facing the cover layer; and
a second shielding layer facing the base insulating layer.

7. The FPCB of claim 1, wherein the cover layer comprises:
a cover insulating layer; and
an adhesive layer bonding the cover insulating layer to the signal layer.

8. The FPCB of claim 6, further comprising:
a first adhesive layer formed on an upper surface of the cover layer at both ends;
a second adhesive layer formed on a lower surface of the base insulating layer at both ends;
a first insulating layer is bonded to the first adhesive layer; and
a second insulating layer is bonded to the second adhesive layer,
wherein the first shielding layer is formed on a surface of the first insulating layer, which is opposite the surface on which the first adhesive layer is bonded, and the second shielding layer is formed on a surface of the second insulating layer, which is opposite the surface on which the second insulating layer is bonded.

9. The FPCB of claim 8, wherein the space comprises:
a first space defined by the first adhesive layer, the first insulating layer and the cover layer; and
a second space defined by the second adhesive layer, the second insulating layer and the base insulating layer.

10. The FPCB of claim 8, further comprising:
a first conductive layer formed on the surface of the first insulating layer at both ends, which is opposite the surface on which the first adhesive layer is bonded; and
a second conductive layer formed on the surface of the second insulating layer at both ends, which is opposite the surface on which the second adhesive layer is bonded,
wherein both ends of the first shielding layer are connected electrically to the first conductive layer and both the ends of the second shielding layer are connected electrically to the second conductive layer.

11. The FPCB of claim 10, wherein:
the first and second conductive layers each comprise an externally connected electrode and a ground electrode,
both the ends of the first shielding layer are connected electrically to the ground electrode of the first conductive layer; and
both the ends of the second shielding layer are connected electrically to the ground electrode of the second conductive layer.

12. The FPCB of claim 10, further comprising:
a first via-hole that electrically connects the externally connected electrode of the first conductive layer to the signal layer; and
a second via-hole that electrically connects the externally connected electrode of the second conductive layer to the signal layer.

13. The FPCB of claim 10, wherein at least one side end of the first and second adhesive layers and the first and second conductive layers is aligned along a straight line in the vertical direction.

14. The FPCB of claim 8, wherein the first and second adhesive layers have a same thickness.

15. The FPCB of claim 1, wherein a number of the at least one shielding layer is one, and the shielding layer is formed to face any one of the base insulating layer and the cover layer across the space therebetween.

16. The FPCB of claim 15, further comprising:
an adhesive layer formed on the surface of any one of the base insulating layer and the cover layer at both ends; and
a shielding insulating layer bonded to the adhesive layer,
wherein the shielding layer is formed on the shielding insulating layer.

17. The FPCB of claim 1, wherein the space is filled with air.

18. The FPCB of claim 10, further comprising:
a third adhesive layer, arranged between the first conductive layer and the first insulating layer, for bonding the first conductive layer to the first insulating layer; and
a fourth adhesive layer, arranged between the second conductive layer and the second insulating layer, for bonding the second conductive layer to the second insulating layer.

19. The FPCB of claim 18, wherein the first and second insulating layers are made of a material that is different from that of the base insulating layer.

20. The FPCB of claim 18, wherein the first and second conductive layers are formed by a metal film.

21. A method for manufacturing a flexible printed circuit board (FPCB) that includes a first single layer FPCB that has an insulating layer, a signal layer and a cover layer, and second and third single FPCBs. each of which has an insulating layer and a signal layer, the method comprising:
(a) stacking the second single FPCB on the first single layer FPCB, wherein the insulating layer of the second single layer FPCB faces the cover layer of the first single layer FPCB across a space therebetween;
(b) stacking the third single FPCB on the first single layer FPCB, wherein the insulating layer of the third single layer FPCB faces the insulating layer of the first single layer FPCB across a space therebetween; and
(c) removing a part of each of the signal layers of the stacked second and third FPCBs; and
(d) forming a shielding layer, which comprises a conductive layer, on the removed part of each of the signal layers.

22. A method for manufacturing a flexible printed circuit board (FPCB) comprising:
(a) preparing a first single layer FPCB, which forms an insulating layer, a signal layer and a cover layer, and at least one second single layer FPCB which forms an insulating layer and a signal layer;
(b) forming an adhesive layer on the surface of any one of the insulating layer and cover layer of the first single layer FPCB, at both ends of the first single layer FPCB;
(c) bonding at least one second single layer FPCB to the adhesive layer and forming at least one space between the first single layer FPCB and at least one second single layer FPCB;
(d) removing the signal layer of at least one second single layer FPCB except for both ends of the signal layer and exposing a part of the insulating layer of at least one second single layer FPCB; and
(e) forming a shielding layer, which comprises a conductive layer, in the exposed part of the insulating layer and a part of both ends of the signal layer of at least one second single layer FPCB.

23. The method of claim 22, further comprising:
forming at least one through-hole extending from the surface of the signal layer of at least one second single layer FPCB through the signal layer of the first single layer FPCB.

24. The method of claim 23, wherein the step (d) further comprises:
(i) forming a plating layer on the signal layer of at least one second single layer FPCB; and
(ii) forming an externally connected electrode and a ground electrode at both ends of the plated signal layer by patterning.

25. The method of claim 24, wherein forming a plating layer comprises:
filling at least one through-hole with a metal material, and thus forming a via-hole that electrically connects the signal layer of at least one second single layer FPCB to the signal layer of the first single layer FPCB.

26. A method for manufacturing an FPCB comprising:
preparing a first single layer FPCB, which forms an insulating layer, a signal layer and a cover layer, and second and third single layer FPCBs each of which forms an insulating layer and a signal layer;
(a) forming a first adhesive layer on the surface of the cover layer of the first single layer FPCB, at both ends of the first single layer FPCB;
(b) forming a second adhesive layer on the surface of the insulating layer of the first single layer FPCB, at both ends of the first single layer FPCB;
(c) bonding both ends of the insulating layer of the second single layer FPCB to the first adhesive layer and forming a first space between the insulating layer of the second single layer FPCB and the cover layer of the first single layer FPCB;
(c) bonding both ends of the insulating layer of the third single layer FPCB to the second adhesive layer and forming a second space between the insulating layer of the first single layer FPCB and the insulating layer of the third single layer FPCB;
(d) removing the signal layers of the second and third single layer FPCBs except for both ends of the signal layers and exposing a part of the insulating layers of the second and third signal layer FPCBs; and
(e) forming a shielding layer, which comprises a conductive layer, in the exposed part of the insulating layers and a part of both ends of the signal layers of the second and third single layer FPCBs.

27. The method of claim 26, further comprising:
(f) forming a first via-hole that electrically connects both ends of the remained signal layer of the second single layer FPCB to the signal layer of the first single layer FPCB; and
(g) forming a second via-hole that electrically connects both ends of the remained signal layer of the third single layer FPCB to the signal layer of the first single layer FPCB.

28. A method for manufacturing an flexible printed circuit board (FPCB) comprising:
(a) providing a single FPCB that forms an insulating layer, a signal layer and a cover layer;
(b) forming a first adhesive layer on the surface of any one of the insulating layer and the cover layer, at both ends of the corresponding layer;
(c) bonding a shielding layer to the first adhesive layer and forming at least one space between the shielding insulating layer and at least one of the insulating layer and the cover layer on which the first adhesive layer is formed;
(c) forming a second adhesive layer on the surface of the shielding insulating layer, at both ends of the shielding layer;
(d) bonding a metal film to the second adhesive layer; and
(e) forming a shielding layer, which comprises a conductive layer, on a portion of the surface of the shielding insulating layer, except for the surface at both the ends on which the second adhesive layer is formed, and on a portion of the metal film.
